(19) United States
(12) Patent Application Publication
(10) Pub. No.: US 2023/0207294 A1
(43) Pub. Date: Jun. 29, 2023

(54) PLASMA CONTROL APPARATUS AND PLASMA PROCESSING SYSTEM

(71) Applicant: SAMSUNG ELECTRONICS CO., LTD., Suwon-si (KR)

(72) Inventors: Hadong JIN, Hwaseong-si (KR); Siyoung KOH, Suwon-si (KR); Namkyun KIM, Pyeongtaek-si (KR); Kyungmin LEE, Gwacheon-si (KR); Sungyong LIM, Seoul (KR); Sungyeol KIM, Yongin-si (KR); Seungbo SHIM, Seoul (KR)

(73) Assignee: SAMSUNG ELECTRONICS CO., LTD., Suwon-si (KR)

(21) Appl. No.: 17/970,163

(22) Filed: Oct. 20, 2022

(30) Foreign Application Priority Data
Dec. 28, 2021 (KR) 10-2021-0189669

(51) Int. Cl. H01J 37/32

(52) U.S. Cl. CPC H01J 37/3299; H01J 37/32082; H01J 37/32155; H01J 37/32174; H01J 37/32541; H01J 37/32568; H01J 37/32642; H01J 2237/334; H01J 2237/24564; H01L 21/6831

(57) ABSTRACT

Provided is a plasma control apparatus including a plasma electrode disposed in a plasma chamber and to which radio frequency (RF) power having a fundamental frequency configured to generate plasma is applied, an edge electrode disposed adjacent to the plasma electrode and corresponding to a plasma edge region, and a plasma control circuit electrically connected to the edge electrode, the plasma control circuit being configured to control an electrical boundary condition in a plasma edge boundary region of a first frequency component, a harmonic wave component generated by nonlinearity of the plasma and intermodulation distortion frequency components generated by a frequency component in the plasma chamber and each of the first frequency component and the harmonic wave component, wherein the plasma control circuit is configured to change the electrical boundary condition to control a standing wave in the plasma chamber.

### CROSS-REFERENCE TO RELATED APPLICATION

This application claims priority under 35 U.S.C. § 119 to Korean Patent Application No. 10-2021-0189669, filed on Dec. 28, 2021 in the Korean Intellectual Property Office (KIPO), the contents of which are herein incorporated by reference in their entirety.

### BACKGROUND

### 1. Field

Example embodiments relate to a plasma control apparatus and a plasma processing system. More particularly, example embodiments relate to a plasma control apparatus for controlling plasma distribution in a plasma chamber and a plasma processing system including the same.

### 2. Description of Related Art

In a plasma processing system, uniformity of plasma in a chamber may be a significant factor on process performance. In particular, since high aspect ratio contact (HARC) etch facilities use high frequency as an output power in order to generate sufficient density, harmonic components of a first frequency (fundamental frequency) and intermodulation distortion (IMD) frequency components generated due to nonlinearity of plasma may have a great influence on a process result.

### SUMMARY

One or more example embodiments provide a plasma control apparatus configured to provide improved plasma uniformity within a plasma chamber.

One or more example embodiments also provide a plasma processing system including the plasma control apparatus.

According to an aspect of an example embodiment, there is provided a plasma control apparatus including a plasma electrode disposed in a plasma chamber and to which radio frequency (RF) power having a fundamental frequency configured to generate plasma is applied, an edge electrode disposed adjacent to the plasma electrode and corresponding to a plasma edge region, and a plasma control circuit electrically connected to the edge electrode, the plasma control circuit being configured to control an electrical boundary condition in a plasma edge boundary region of a first frequency component, a harmonic wave component generated by nonlinearity of the plasma and intermodulation distortion frequency components generated by a frequency component in the plasma chamber and each of the first frequency component and the harmonic wave component, wherein the plasma control circuit is configured to change the electrical boundary condition to control a standing wave in the plasma chamber.

According to another aspect of an example embodiment, there is provided a plasma processing system including a plasma chamber including a plasma electrode, a plasma power supply configured to apply radio frequency (RF) power having a fundamental frequency to the plasma electrode to generate plasma, an edge electrode disposed adjacent to the plasma electrode and corresponding to a plasma edge boundary region, a plasma control circuit electrically connected to the edge electrode, the plasma control circuit being configured to change an electrical boundary condition in the plasma edge boundary region based on an inputted control signal, a sensor configured to obtain electrical signal data of the edge electrode, and a processor configured to obtain the electrical boundary condition in the plasma edge boundary region based on the electrical signal data obtained by the sensor and output the control signal to the plasma control circuit to obtain a desired electrical boundary condition.

According to another aspect of an example embodiment, there is provided a plasma processing system including a plasma chamber providing a space configured to process a substrate, a substrate stage disposed within the plasma chamber to support the substrate, the substrate stage including a lower electrode, a plasma power supply configured to apply radio frequency (RF) power having a fundamental frequency to the lower electrode to generate plasma, an edge electrode disposed adjacent to the lower electrode and configured to control an electrical boundary condition in a plasma edge boundary region, a plasma control circuit electrically connected to the edge electrode, the plasma control circuit being configured to change the electrical boundary condition in the plasma edge boundary region of a first frequency component, a harmonic wave component generated by nonlinearity of the plasma and intermodulation distortion frequency components generated by a frequency component in the plasma chamber and each of the first frequency component and the harmonic wave component, a sensor configured to obtain electrical signal data of the edge electrode, and a processor configured to obtain the electrical boundary condition in the plasma edge boundary region based on the electrical signal data obtained by the sensor and output a control signal to the plasma control circuit to obtain a desired electrical boundary condition..

### BRIEF DESCRIPTION OF THE DRAWINGS

The above and/or other aspects and features of the present disclosure will become more apparent by describing in detail example embodiments thereof with reference to the attached drawings, in which:

FIG. 1 is a block diagram illustrating a plasma processing system in accordance with example embodiments;

FIG. 2 is a block diagram illustrating a plasma control apparatus in FIG. 1;

FIG. 3 is a circuit diagram illustrating the plasma control circuit in FIG. 2;

FIG. 4 is a view illustrating high frequency components within a plasma chamber in FIG. 1;

FIG. 5 is a circuit block diagram illustrating a plasma control circuit connected to an edge electrode in FIG. 4;

FIG. 6 is graphs illustrating an etch rate distribution according to boundary conditions in an edge boundary region;

FIG. 7 is a circuit block diagram illustrating a plasma control circuit of a plasma control apparatus in accordance with example embodiments;

FIG. 8 is a flow chart illustrating a plasma processing method in accordance with example embodiments;

FIG. 9 is a block diagram illustrating a plasma processing system in accordance with example embodiments;

FIG. 10 is a diagram illustrating high frequency components in the plasma chamber in FIG. 9; and

FIG. 11 is a block diagram illustrating a plasma processing system according to example embodiments.

### DETAILED DESCRIPTION OF EXAMPLE EMBODIMENTS

Hereinafter, example embodiments will be explained in detail with reference to the accompanying drawings.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

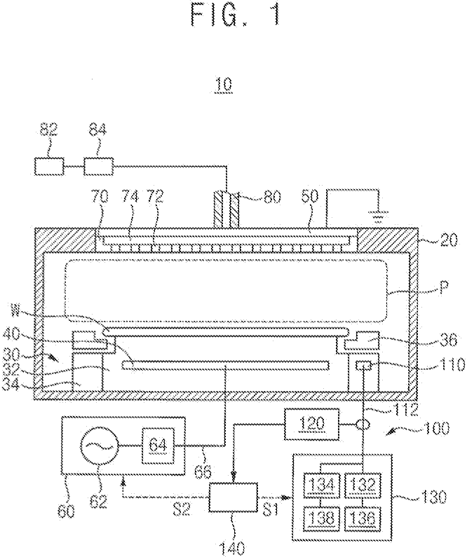

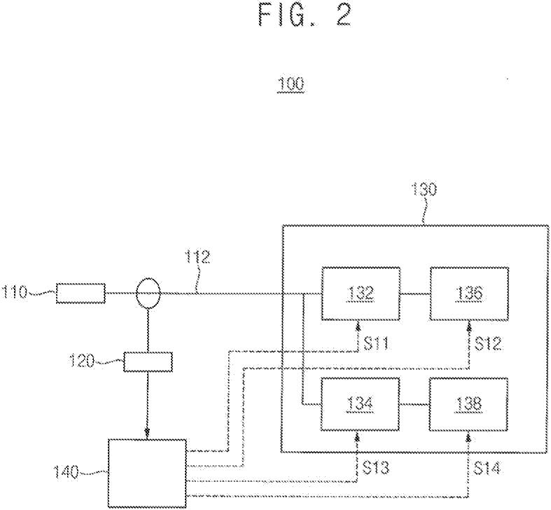

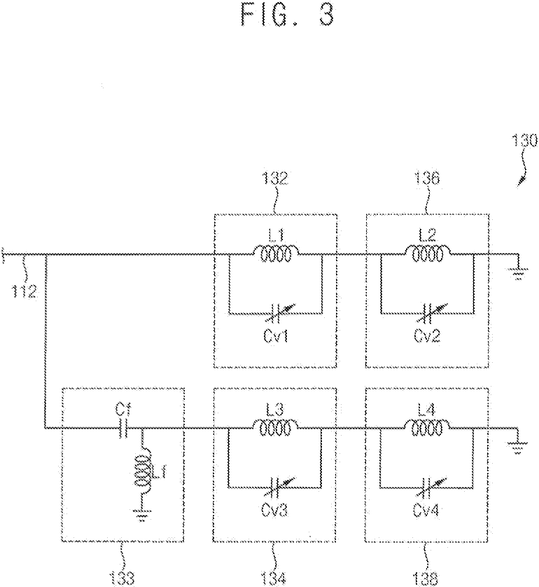

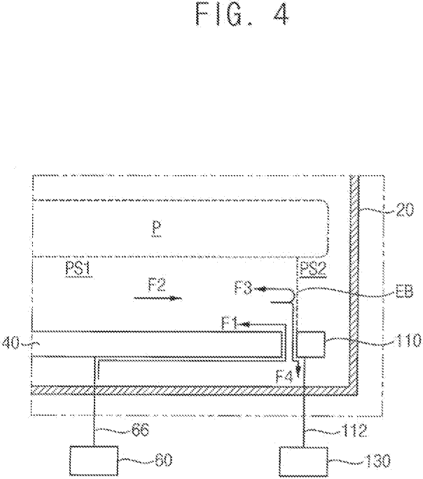

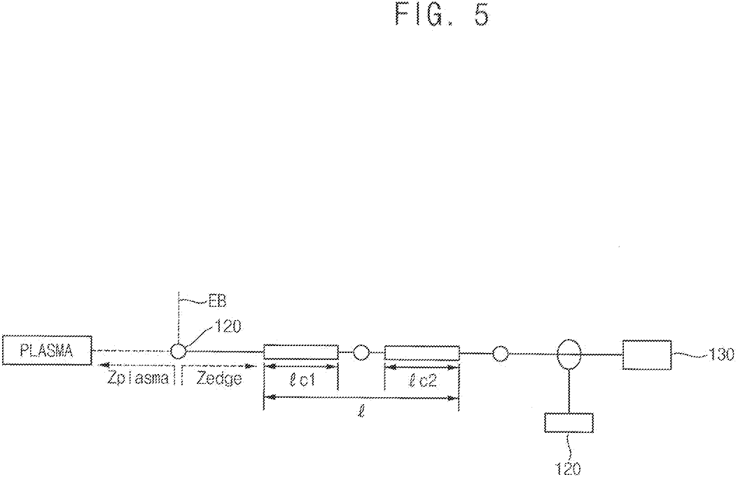

FIG. 1 is a block diagram illustrating a plasma processing system in accordance with example embodiments. FIG. 2 is a block diagram illustrating a plasma control apparatus in FIG. 1. FIG. 3 is a circuit diagram illustrating the plasma control circuit in FIG. 2. FIG. 4 is a view illustrating high frequency components within a plasma chamber in FIG. 1. FIG. 5 is a circuit block diagram illustrating a plasma control circuit connected to an edge electrode in FIG. 4.

Referring to FIGS. 1 to 5, a plasma processing system 10 may include a chamber 20 configured to provide a space for performing a plasma process on a substrate such as a wafer W, a substrate stage 30 configured to support the substrate and having a lower electrode 40, an upper electrode 50 and a plasma control apparatus 100. In addition, the plasma processing system 10 may further include a plasma power supply, a gas supply, an exhaust portion, etc. The plasma control apparatus 100 may include an edge electrode 110, a sensor 120, a plasma control circuit 130 and a controller 140.

In example embodiments, the plasma processing system 10 may be an apparatus configured to etch a target layer on a substrate such as a semiconductor wafer W disposed within a capacitively coupled plasma (CCP) chamber 20. However, the plasma generated by the plasma processing system is not limited to the capacitively coupled plasma, and, for example, inductively coupled plasma may be generated by the plasma processing apparatus. In addition, the plasma processing system may not be limited to the etching apparatus, and, for example, may be used as a deposition apparatus, a cleaning apparatus, etc. Here, the substrate may include a semiconductor substrate, a glass substrate, etc.

The chamber 20 may provide a sealed space where a plasma etching process is performed on the wafer W. The chamber 20 may be, for example, a cylindrical shaped vacuum chamber. The chamber 20 may include a metal such as aluminum, stainless steel, etc. A gate configured to load and unload the wafer W may be provided in a sidewall of the chamber 20. The wafer W may be loaded/unloaded onto/from the substrate stage through the gate.

An exhaust port may be provided at a bottom portion of the chamber 20, and the exhaust portion may be connected to the exhaust port through an exhaust line. The exhaust portion may include a vacuum pump such as a turbo molecular pump or the like, to control a pressure of the chamber so that the processing space inside the chamber 20 may be depressurized to a desired vacuum level. Additionally, process by-products and residual process gases generated in the chamber 20 may be discharged through the exhaust port.

The substrate stage 30 may be disposed within the chamber 20 to support the substrate. For example, the substrate stage 30 may serve as a susceptor configured to support the wafer W thereon. The substrate stage 30 may include a support plate 32 having an electrostatic electrode thereon for holding the wafer W using electrostatic force. The electrostatic electrode may adsorb and hold the wafer W with the electrostatic force by a DC voltage supplied from a DC power supply. In addition, the support plate may have a circulation channel for cooling therein. In addition, for precision of wafer temperature control, a cooling gas such as helium (He) gas may be supplied between the electrostatic chuck and the wafer W.

The substrate stage 30 may include the disk-shaped lower electrode 40 on the support plate 32. The substrate stage 30 may be installed to be movable up and down by a driving mechanism. The lower electrode 40 may include a plate, a perforated plate, a wire screen, or any other distributed arrangement. The lower electrode 40 may include a sheet type or mesh type electrode.

In example embodiments, a focus ring 36 may be disposed adjacent to and to surround an outer circumferential surface of the wafer W seated on the support plate 32. The focus ring 36 may be disposed on an outer insulating ring 34 disposed around the substrate stage 30. The focus ring 36 may have a ring shape to surround the wafer W. The edge electrode 110 may be disposed in the outer insulating ring 34. The edge electrode 110 may be disposed under the focus ring 36. The edge electrode 110 may have an annular shape. The edge electrode 110 may be provided adjacent to and surround the lower electrode 40 and may be arranged to be spaced apart from the lower electrode 40.

The lower electrode 40 may be provided in a first region corresponding to the wafer W inside the support plate 32, and the edge electrode 110 may be provided in a second region corresponding to a peripheral region of the wafer W inside the outer insulating ring 34 surrounding the support plate 32. The first region may be referred to as a central region PS1 of a plasma (or plasma sheath) region, and the second region may be referred to as an edge region PS2 of the plasma (or plasma sheath) region.

The edge electrode 110 may directly contact the focus ring 36 or may be electrically connected to the focus ring 36. As will be described later, the plasma control apparatus 100 may be electrically connected to the edge electrode 110 to form an independent circuit path through the plasma control circuit 130 in a plasma edge boundary region EB. An electrical boundary condition may be adjusted to change an electric field distribution of a standing wave in the chamber 20 to thereby improve uniformity of the plasma. Additionally, the focus ring 36 may prevent plasma from being concentrated on the outer peripheral surface of the wafer W during a plasma processing process performed on the wafer W.

The substrate stage 30 may include metallic or ceramic materials. For example, the metallic or ceramic materials may include at least one metal, metal oxide, metal nitride, metal oxynitride or a combination thereof. The substrate stage 30 may include aluminum, aluminum oxide, aluminum nitride, aluminum oxynitride or a combination thereof.

The outer insulating ring 34 may have a structure provided adjacent to and surrounding the lower electrode 40. For example, the outer insulating ring 34 may include an insulating material such as alumina. The focus ring 36 may include a metal such as aluminum or an insulating material.

In example embodiments, the plasma power supply may include a first power supply 60 configured to apply plasma source power to the lower electrode 40. For example, the first power supply 60 may include an RF power source 62 and an RF matcher 64 as plasma source elements. The RF power source 62 may generate a radio frequency (RF) signal.

The RF power source 62 may include at least one source. For example, the RF power source 62 may include a first source configured to generate RF power having a first frequency (fundamental frequency) in a range of several MHz to several tens of MHz. In addition, the RF power source 62 may further include a second source configured to generate RF power having a second frequency in a lower range than the first frequency. The high frequency RF power from the first source may serve to generate plasma and the low frequency RF power from the second source may serve to supply energy to ions. However, embodiments are not limited thereto, and the RF power source may include three or more sources, and the low frequency RF power may have various functions.

An RF matcher 64 may match impedance of the RF signal generated from the RF power source 62 so that RF power may be optimally delivered to the plasma chamber 20. For example, the RF matcher 64 may maximize RF power delivery by adjusting the impedance so that a complex conjugate condition is satisfied based on a maximum power delivery theory.

The RF matcher 64 may include two sub matchers corresponding to each frequency of the RF power. For example, the RF matcher 64 may include a first sub matcher corresponding to the first frequency of the first source and a second sub matcher corresponding to the second frequency of the second source.

A first transmission line 66 may be disposed between the first power supply 60 and the plasma chamber 20 to transmit RF power to the plasma chamber 20. The first transmission line 66 may electrically connect the first power supply 60 and the lower electrode 40. The first transmission line 66 may be implemented as, for example, a coaxial cable, an RF strap, an RF rod, etc. The coaxial cable may include a center conductor, an outer conductor, an insulator and an outer sheath. The coaxial cable may have a structure in which the center conductor and the outer conductor are coaxially arranged.

The controller 140 may be connected to the first power supply 60 and the plasma control apparatus 100 to control their operations. The controller having a microcomputer and various interface circuits may control an operation of the plasma processing system based on programs and recipe information stored in an external or internal memory. For example, the controller 140 may output a second control signal S2 to the first power supply 60 to control the RF frequency, RF transmission characteristics, etc. The controller 140 may include a simple controller, a microprocessor, a complex processor such as a central processing unit (CPU) or a graphics processing unit (GPU), a processor configured by software, or dedicated hardware or firmware. For example, the controller 140 may be implemented by a general-use computer or an application-specific hardware component such as a digital signal processor (DSP), a field programmable gate array (FPGA), or an application-specific integrated circuit (ASIC).

The upper electrode 50 may be disposed over the substrate stage 30 to face the lower electrode 40. A chamber space between the upper electrode 50 and the lower electrode 40 may be used as a plasma generating region. The upper electrode 50 may be connected to the ground. According to another example embodiment, a second power supply may be provided to supply RF power to the upper electrode 50. In this case, the upper electrode 50 may receive the RF power from the second power supply, and may excite a source gas that is supplied into the chamber 20, into plasma in synchronization with the lower electrode 40.

The upper electrode 50 may be provided as a portion of a shower head for supplying gas into the chamber 20. The upper electrode 50 may include an electrode plate having a circular shape. The upper electrode 50 may be formed to have a plurality of supply holes configured to supply gas into the chamber 20.

In particular, the shower head may support the upper electrode 50 and may include a shower head body 70 configured to introduce the gas that is supplied through the upper electrode 50 into the chamber 20. The shower head body 70 may include a gas diffusion chamber 74 therein, and the gas diffusion chamber 74 may be connected to spraying holes 72 formed in the shower head body 70.

The gas supply may include a gas supply line 80, a flow controller 84 and a gas supply source 82 as gas supply elements. The gas supply line 80 may be connected to the gas diffusion chamber 74 of the shower head body 72 through the supply holes of the upper electrode 50, and the flow controller 84 may control a supply amount of the gas supplied into the chamber 20 through the gas supply line 80. For example, the gas supply source 82 may include a plurality of gas tanks, and the flow controller 84 may include a plurality of mass flow controllers (MFC) respectively corresponding to the gas tanks. The mass flow controllers may independently control the supply flow rates of the gases respectively.

The first power supply 60 may apply RF power to the lower electrode 40 to generate plasma from a process gas in the chamber 20 using an RF electric field formed on the lower electrode 40.

In example embodiments, the plasma control apparatus 100 may change an electrical boundary condition in a plasma edge boundary region EB on the focus ring 36 to control a standing wave in the plasma chamber to thereby control plasma distribution over the entire area (center-middle-edge) of the wafer W.

In particular, the plasma control circuit 130 may be electrically connected to the edge electrode 110 by the second transmission line 112. The plasma control circuit 130 may serve as a reflector configured to change the electrical boundary condition in the plasma edge boundary region EB in response to the first control signal S1 input from the controller 140. The plasma control circuit 130 may control characteristic impedance of the edge region PS2 of the plasma (or plasma sheath) region adjacent to the focus ring 36 to control the electrical boundary condition in the plasma edge boundary region EB.

The sensor 120 may be installed on the second transmission line 112 to obtain electrical signal data of the edge electrode 110. For example, the sensor 120 may include a voltage current sensor (VI sensor). The voltage-current measurement sensor may detect voltage (V), current (I) and phase (Ø) of the first frequency component as well as harmonic wave and intermodulation distortion (IMD) components.

The controller 140 may calculate and obtain an electrical boundary condition in the plasma edge boundary region EB based on the electrical signal data obtained by the sensor 120 and may output the first control signal S1 to the plasma control circuit 130 in order to obtain a desired electrical boundary condition.

As illustrated in FIG. 4, when the RF component F1 having the first frequency (eg, 60 MHz) is applied to the lower electrode 40, the RF component may move along a surface thereof to generate plasma P in the plasma chamber 20. When the RF power having the first frequency is applied to the plasma chamber 20, additional components (harmonic wave component, intermodulation distortion (IMD) frequency component) may be generated due to nonlinearity of the plasma.

Some frequency components F2 among the high frequency components existing in the plasma sheath may travel to the edge boundary region EB. The central region PS1 of the plasma sheath may have a first medium by a power source circuit connected to the lower electrode 40 with the edge boundary region EB interposed therebetween, and the edge region PS2 of the plasma sheath may have a second medium different from the first medium by the plasma control circuit 130 connected to the edge electrode 110.

Accordingly, the frequency components F2 traveling to the edge boundary region EB may be partially reflected in the edge boundary region EB due to a difference between the first medium and the second medium, and some high-frequency components F3 may be reflected back into the plasma sheath and some high-frequency components F4 may pass through and proceed to the edge electrode 110. The traveling wave F2 traveling to the edge boundary region EB in the plasma sheath and the reflected wave F3 reflected from the edge boundary region EB may meet in the central region PS1 to form a standing wave. In the central region PS1 of the plasma sheath, the traveling wave and the reflected wave having the first frequency may meet each other to form a standing wave, and the traveling wave and the reflected wave having the harmonic component may meet each other to form a standing wave, and the traveling wave and the reflected wave having the intermodulation frequency component may meet each other to form a standing wave.

Amounts and phases of the standing waves present in the central region PS1 in the plasma (or plasma sheath) may be adjusted to control a plasma distribution over the entire area (center-middle-edge) on the wafer W. An amount of reflection of the high frequency component in the plasma edge boundary region EB may be adjusted to control amounts and phases of the standing waves. The amount of reflection of the high frequency component in the plasma edge boundary region EB may be determined by a boundary condition in the edge boundary region EB. For example, the amounts of reflection and transmission of the traveling wave may be changed according to the boundary condition in the edge boundary region.

As illustrated in FIGS. 2 and 3, the plasma control circuit 130 may include an impedance control circuit configured to control an electrical boundary condition in the plasma edge boundary region EB of the first frequency component, the harmonic component generated by nonlinearity of plasma and the intermodulation frequency components generated by the frequency component and each of the first frequency component and the harmonic component.

The plasma control circuit 130 may include a fundamental frequency control circuit 132 configured to change a boundary condition of the first frequency (fundamental wave), a first intermodulation frequency control circuit 136 configured to change a boundary condition of the intermodulation frequency component generated by the first frequency component and the frequency component in the plasma chamber, a harmonic frequency control circuit 134 configured to change a boundary condition of the harmonic component, and a second intermodulation frequency control circuit 138 configured to change a boundary condition of the intermodulation frequency component generated by the harmonic component and the frequency component in the plasma chamber.

The fundamental frequency control circuit 132 and the harmonic frequency control circuit 134 may be connected in parallel to the edge electrode 110. The first intermodulation frequency control circuit 136 may be connected in series to the fundamental frequency control circuit 132. The second intermodulation frequency control circuit 138 may be connected in series to the harmonic frequency control circuit 134.

The fundamental frequency control circuit 132 may include a fundamental frequency resonance circuit configured to generate a resonance for the first frequency (fundamental wave). The fundamental frequency control circuit 132 may have a circuit structure in which a first inductor L1 and a first variable capacitor Cv1 are connected in parallel. A capacitance of the first variable capacitor Cv1 may be varied by a first control signal S11 from the controller 140 to determine impedance Zh1 of the fundamental frequency resonance circuit. However, embodiments are not limited thereto, and the fundamental frequency control circuit 132 may have a circuit structure in which the first inductor L1 and the first variable capacitor Cv1 are connected in series.

The first intermodulation frequency control circuit 136 may include a first intermodulation frequency resonant circuit configured to generate a resonance for the first intermodulation frequency. The first intermodulation frequency control circuit 136 may have a circuit structure in which a second inductor L2 and a second variable capacitor Cv2 are connected in parallel. A capacitance of the second variable capacitor Cv2 may be varied by a first control signal S12 from the controller 140 to determine impedance Zimd1 of the first intermodulation frequency resonance circuit. However, embodiments are not limited thereto, and the first intermodulation frequency control circuit 136 may have a circuit structure in which the second inductor L2 and the second variable capacitor Cv2 are connected in series.

The harmonic frequency control circuit 134 may include a harmonic frequency resonance circuit configured to generate a resonance for the harmonic frequency. The harmonic frequency control circuit 132 may have a circuit structure in which a third inductor L3 and a third variable capacitor Cv3 are connected in parallel. A capacitance of the third variable capacitor Cv3 may be varied by a first control signal S13 from the controller 140 to determine impedance Zh2 of the harmonic frequency resonance circuit. However, embodiments are not limited thereto, and the harmonic frequency control circuit 132 may have a circuit structure in which the third inductor L3 and the third variable capacitor Cv3 are connected in series.

The second intermodulation frequency control circuit 138 may include a second intermodulation frequency resonant circuit configured to generate a resonance for the second intermodulation frequency. The second intermodulation frequency control circuit 138 may have a circuit structure in which a fourth inductor L4 and a fourth variable capacitor Cv4 are connected in parallel. A capacitance of the fourth variable capacitor Cv4 may be varied by a first control signal S14 from the controller 140 to determine impedance Zimd2 of the second intermodulation frequency resonance circuit. However, embodiments are not limited thereto, and the second intermodulation frequency control circuit 138 may have a circuit structure in which the fourth inductor L4 and the fourth variable capacitor Cv4 are connected in series.

In addition, the plasma control circuit 130 may further include a first frequency blocking filter circuit 133 provided in front of the harmonic frequency control circuit unit 134 to blocking progress of the first frequency (fundamental frequency). For example, the first frequency blocking filter circuit 133 may have a circuit structure including a capacitor Cf connected in series and an inductor Lf connected in parallel.

It will be understood that the circuit structure of the plasma control circuit is not limited thereto, and may be variously changed depending on the overall circuit characteristics of the plasma control system and the characteristic impedance appearing in the edge boundary region.

Hereinafter, a method of calculating and obtaining a reflection amount of the high frequency component in the plasma edge boundary region will be explained.

As illustrated in FIG. 5, the reflection amount in the plasma edge boundary region EB may be determined by impedance Zc of the plasma control circuit 130. The controller 140 may calculate and obtain an electrical boundary condition in the plasma edge boundary region EB based on the electrical signal data obtained by the sensor 120 and output the first control signal S1 to the plasma control circuit 130 in order to obtain a desired electrical boundary condition (reflection amount).

First, the impedance Zc of the plasma control circuit 130 may be calculated and obtained from the electrical signal data (voltage Vc, current Ic, and phase (Ø_{c})) obtained by the sensor 120, and may be expressed by following equation (1).

$${Z}_{c} = \left|\frac{{V}_{c}}{{I}_{c}}\right| ∗ \left(cos {∅}_{c} + j sin {∅}_{c}\right)$$

The edge electrode 110 may be electrically connected to the plasma control circuit 130 as a load located at an end of a transmission line, that is, the second transmission line 112 by the transmission line having characteristic impedance Z0. In a structure to which RF power having a high frequency is transmitted, since voltage and current values vary according to a physical location (length), impedance may vary depending on the length of the structure. In this circuit structure, the impedance (Zedge) of the edge electrode 110 may be expressed by an input impedance equation expressed in terms of load and characteristic impedance as shown in Equation (2) below.

$${Z}_{e d g e} = {Z}_{0} ∗ \frac{{Z}_{c} + j {Z}_{0} tan \left(β l\right)}{{Z}_{0} + j {Z}_{c} tan \left(β l\right)}$$

Here, β is phase constant (2π/λ).

The transmission line may have a first physical distance lc1 between the chamber 20 and the edge electrode 110 and a second physical distance lc2 between the plasma control circuit 130 and the chamber 20. Accordingly, the characteristic impedance Z0 of the transmission line may be calculated by a combination of impedances of the first and second physical distances lc1 and lc2. In this case, the characteristic impedance Z0 or the physical lengths lc1 and lc2 are constant values determined by the configuration of the chamber. Accordingly, it may be seen that the impedance Zedge of the edge electrode 110 changes according to the impedance Zc of the plasma control circuit 130.

The amount of reflection Γ in the edge boundary area EB generated by a difference in electrical characteristics between the lower electrode 40 and the edge electrode 110 may be calculated by following Equation (3).

$$\text{Γ} = \frac{{Z}_{e d g e} - {Z}_{p l a s m a}}{{Z}_{e d g e} + {Z}_{p l a s m a}}$$

Here, Zplasma is impedance of the plasma.

Since the impedance Zplasma of plasma is constant, it may be seen that the amount of reflection Γ changes according to the impedance Zedge of the edge electrode 110. Accordingly, the reflection amount Γ in the edge boundary region EB may be determined by the impedance Zc of the plasma control circuit 130.

Thus, the controller 140 may calculate and obtain an electrical boundary condition in the plasma edge boundary region EB based on the electrical signal data obtained by the sensor 120 and change the impedance (Zc) of the plasma control circuit 130 to obtain a desired electrical boundary condition.

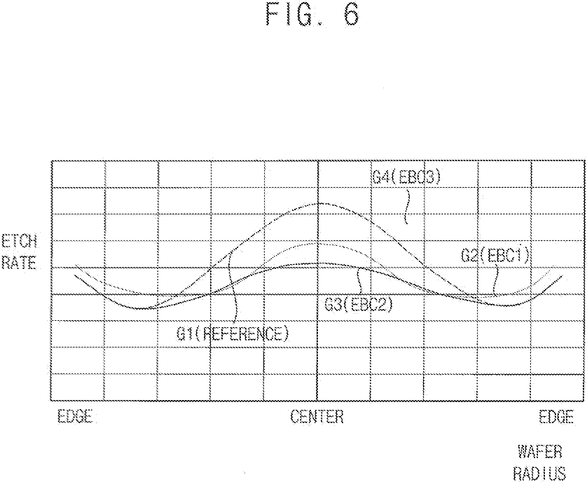

FIG. 6 is graphs illustrating an etch rate distribution according to boundary conditions in an edge boundary region.

Referring to FIG. 6, graph G1 shows an etch rate according to a wafer radius when the plasma control apparatus 100 is not provided according to a related example, and graph G2, graph G3 and graph G4 show an etching rate according to the wafer radius when the plasma control apparatus 100 is provided according to example embodiments. The graph G2, the graph G3 and the graph G4 are graphs showing etch rate distributions under different boundary conditions in the plasma edge boundary region EB.

As shown in graph G2, regarding the etch rate distribution in a first electrical boundary condition (EBC1), when compared to the related example (graph G1), the etch rate at the center of the wafer may be decreased and the etch rate at the edge of the wafer may be increased, to improve the plasma distribution across the entire region (center-middle-edge).

As shown in graph G3, regarding the etch rate distribution in a second electrical boundary condition (EBC2), when compared to the related example (graph G1), the etch rate at the center of the wafer may be reduced, to improve the plasma distribution across the entire region (center-middle-edge).

As shown in graph G4, regarding the etch rate distribution in a third electrical boundary condition (EBC3), when compared to the related example (graph G1), the etch rate at the center, middle and edge of the wafer may be increased to improve the plasma distribution across the entire region (center-middle-edge).

As described above, the plasma processing system 10 may include the plasma chamber 20 having the lower electrode 40 as the plasma electrode to which RF power having at least one fundamental frequency (first frequency) is applied, and the plasma control apparatus 100 configured to change the electrical boundary condition in the plasma edge boundary region to control the standing wave in the plasma chamber. The plasma control apparatus 100 may include the edge electrode 110 disposed adjacent to and around the lower electrode 40 and the plasma control circuit 130 electrically connected to the edge electrode 40 to change the electrical boundary condition in response to the inputted control signal S1.

The plasma control circuit 130 may control the electrical boundary condition in the plasma edge boundary region EB for the first frequency component, the harmonic component generated by nonlinearity of the plasma and the intermodulation frequency components generated by the frequency component within the plasma chamber and each of the first frequency component and the harmonic component.

Accordingly, the electrical boundary condition in the plasma edge boundary region EB may be changed to control the standing waves in the plasma chamber, to thereby control the plasma distribution over the entire region (center-middle-edge) on the wafer W.

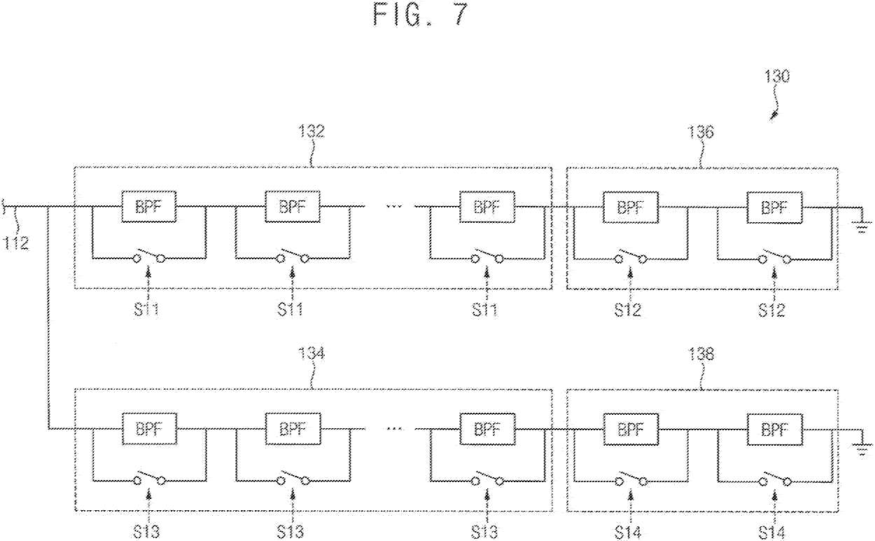

FIG. 7 is a circuit block diagram illustrating a plasma control circuit of a plasma control apparatus in accordance with example embodiments. FIG. 7 is a circuit block diagram illustrating the plasma control circuit in FIG. 2.

Referring to FIG. 7, a plasma control circuit 130 may include a filter control circuit configured to control an electrical boundary condition in a plasma edge boundary region EB of a first frequency component, a harmonic component generated by nonlinearity of plasma, and intermodulation frequency components generated by a frequency component in a plasma chamber and each of the first frequency component and the harmonic component.

The plasma control circuit 130 may include a fundamental frequency control circuit 132 configured to change a boundary condition of the first frequency (fundamental wave), a first intermodulation frequency control circuit 136 configured to change a boundary condition of the intermodulation frequency component generated by the first frequency component and the frequency component in the plasma chamber, a harmonic frequency control circuit 134 configured to change a boundary condition of the harmonic component, and a second intermodulation frequency control circuit 138 configured to change a boundary condition of the intermodulation frequency component generated by the harmonic frequency component and the frequency component in the plasma chamber.

Each of the fundamental frequency control circuit 132, the first intermodulation frequency control circuit 136, the harmonic frequency control circuit 134, and the second intermodulation frequency control circuit 138 may include band pass filters (BPF) connected to each other in series and switches for switching an operation of each of the band pass filters. The switches may be turned ON and OFF by second control signals S11, S12, S13 and S14 from a controller 140 respectively. The controller 140 may serve as a filter control circuit that selectively operates the band-pass filters through the switches to pass only a specific range of frequencies.

Hereinafter, a method of processing a substrate using the plasma processing system of FIG. 1 will be explained.

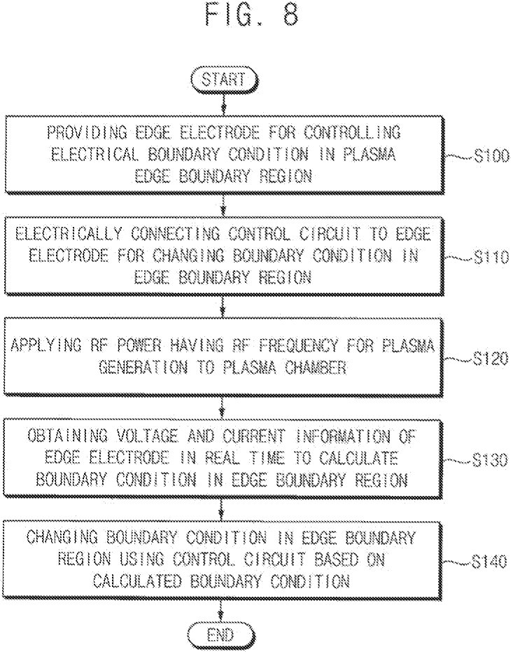

FIG. 8 is a flow chart illustrating a plasma processing method in accordance with example embodiments.

Referring to FIGS. 1 to 8, an edge electrode 110 configured to control an electrical boundary condition in a plasma edge boundary region EB may be provided (S100).

In example embodiments, the edge electrode 110 may be disposed within an outer insulating ring 34 that is provided adjacent to and surrounds a support plate 32 of a substrate stage 30. The edge electrode 110 may be disposed under a focus ring 36 that has an annular shape to surround a wafer W. The edge electrode 110 may have an annular shape. The edge electrode 110 may be provided adjacent to and surround a lower electrode 40 in the support plate 32 and may be arranged to be spaced apart from the lower electrode.

The lower electrode 40 may be provided in a first region corresponding to the wafer W inside the support plate 32, and the edge electrode 110 may be provided in a second region corresponding to a peripheral region of the wafer W inside the outer insulating ring 34 surrounding the support plate 32. The first region may be referred to as a central region PS1 of a plasma (or plasma sheath) region, and the second region may be referred to as an edge region PS2 of the plasma (or plasma sheath) region.

A plasma control circuit 130 configured to change the electrical boundary condition in the edge boundary region EB may be electrically connected to the edge electrode 110 (S110).

The plasma control circuit 130 may be electrically connected to the edge electrode 110 to form an independent circuit path. The plasma control circuit 130 may change the electrical boundary condition in response to an inputted control signal S1.

In particular, the plasma control circuit 130 may include an impedance control circuit or a filter control circuit configured to control the electrical boundary condition in the plasma edge boundary region EB of a first frequency component, a harmonic component generated by nonlinearity of the plasma and intermodulation frequency components generated by a frequency component in the plasma chamber and each of the first frequency component and the harmonic component.

Then, RF power having the first frequency (RF frequency) for plasma generation may be supplied to the plasma chamber 20 (S120).

As illustrated in FIG. 4, a first power supply 60 may supply a RF component F1 having a first high frequency (eg, 60 MHz) to the lower electrode 40. The RF component may move along a surface of the substrate stage 30 including the lower electrode 40 to form plasma P in the plasma chamber 20. When the RF power having the first frequency is applied to the plasma chamber 20, additional components (harmonic wave component, intermodulation distortion (IMD) frequency component) may be generated due to nonlinearity of the plasma.

Some frequency components F2 among the high frequency components existing in the plasma sheath may travel to the edge boundary region EB in the plasma sheath. The central region PS1 of the plasma sheath may have a first medium by a power source circuit connected to the lower electrode 40 with the edge boundary region EB interposed therebetween, and the edge region PS2 of the plasma sheath may have a second medium different from the first medium by the plasma control circuit 130 connected to the edge electrode 110.

Accordingly, the frequency components F2 traveling to the edge boundary region EB may be partially reflected in the edge boundary region EB due to the difference between the first media and the second media, and some high frequency components F3 may be reflected back into the plasma sheath, while some high frequency components F4 may pass through and proceed to the edge electrode 110. The traveling wave F2 traveling to the edge boundary region EB in the plasma sheath and the reflected wave F3 reflected from the edge boundary region EB may meet in the central region PS1 to form a standing wave. In the central region PS1 of the plasma sheath, the traveling wave and the reflected wave having the first frequency may meet each other to form a standing wave, the traveling wave and the reflected wave having the harmonic component may meet each other to form a standing wave, and the traveling wave and the reflected wave having the intermodulation frequency component may meet each other to form a standing wave.

Then, voltage information and current information of the edge electrode 110 may be obtained in real time to calculate and obtain a boundary condition in the edge boundary region (S130), and the boundary condition in the boundary area EB may be changed using the plasma control circuit 130 based on the calculated boundary condition (S140).

In example embodiments, the sensor 120 may be installed on a second transmission line 112 to obtain electrical signal data of the edge electrode 110. For example, the sensor 120 may include a voltage current sensor (VI) sensor. The voltage current measuring sensor may detect voltage (V), current (I) and phase (Ø) of the first frequency as well as the harmonic waves and the intermodulation distortion (IMD) components.

The controller 140 may calculate and obtain an electrical boundary condition in the plasma edge boundary region EB based on the electrical signal data obtained by the sensor 120 and output the first control signal S1 to the plasma control circuit 130 in order to obtain a desired electrical boundary condition.

For example, an amount of reflection Γ (boundary condition) in the edge boundary region EB generated by the difference in electrical characteristics between the lower electrode 40 and the edge electrode 110 may be determined by the impedance Zc of the plasma control circuit 130.

The plasma control circuit 130 may serve as a reflector configured to change the electrical boundary condition in the plasma edge boundary region EB in response to the first control signal S1 inputted from the controller 140.

Accordingly, the amount and phase of the standing wave may be controlled by controlling the reflection amount of the high frequency component in the plasma edge boundary region EB. Thus, the amount and phase of the standing waves existing in the central area PS1 in the plasma (plasma sheath) may be changed to control plasma distribution over the entire region (center-middle-edge) on the wafer W.

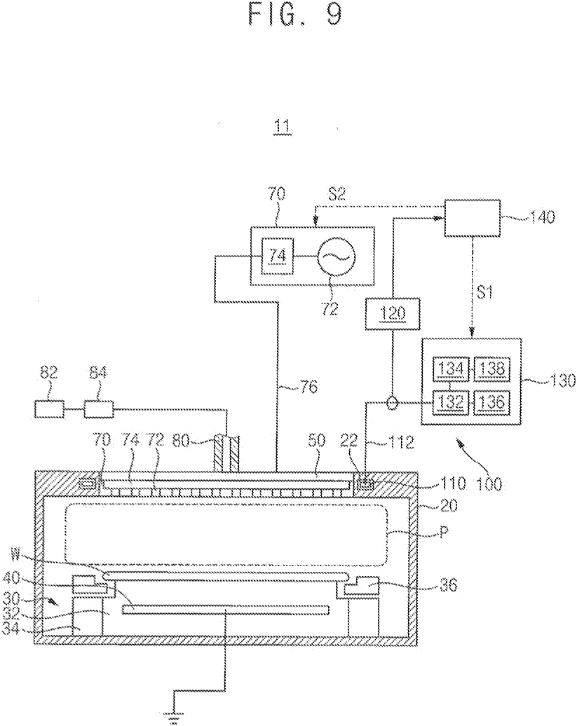

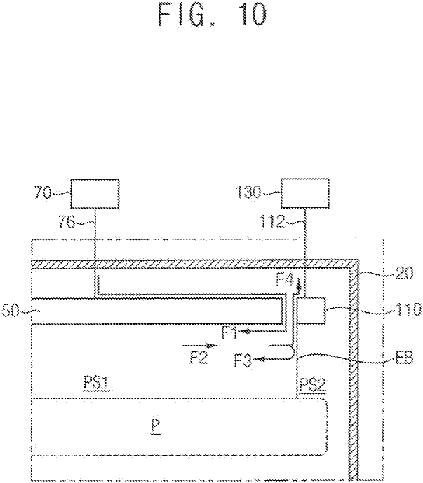

FIG. 9 is a block diagram illustrating a plasma processing system in accordance with example embodiments. FIG. 10 is a diagram illustrating high frequency components in the plasma chamber in FIG. 9. The plasma processing system may be substantially the same as or similar to the plasma processing system described with reference to FIGS. 1 to 5 except for arrangements of a plasma power supply and a plasma control apparatus. Thus, same reference numerals will be used to refer to the same or like elements and any further repetitive explanation concerning the above elements will be omitted.

Referring to FIGS. 9 and 10, a plasma power supply of a plasma processing system 11 may include a second power supply 70 configured to apply plasma source power to an upper electrode 50 .

In example embodiments, the second power supply 70 may include an RF power source 72 and an RF matcher 76 as plasma source elements. The RF power source 72 may generate a radio frequency (RF) signal. A first transmission line 76 may be disposed between the second power supply 70 and a plasma chamber 20 to transmit RF power to the plasma chamber 20. The second power supply may be substantially the same as or similar to the first power supply in FIG. 1. Thus, a detailed description thereof will be omitted.

A lower electrode 40 may be connected to the ground. According to another example embodiment, a first power supply may be provided to supply RF power to the lower electrode 40. In this case, the lower electrode 40 may receive RF power from the first power supply, and may excite a source gas supplied into the chamber 20 into plasma in synchronization with the upper electrode 50.

In example embodiments, the edge electrode 110 may be disposed in an outer insulating ring 22 provided in an upper portion of the chamber 20 provided adjacent to and surrounding a shower head body 70. The outer insulating ring 22 may have a structure surrounding the shower head body 70. For example, the outer insulating ring 22 may include an insulating material such as alumina. The edge electrode 110 may have an annular shape. The edge electrode 110 may surround the upper electrode 50 and may be arranged to be spaced apart from the upper electrode. However, embodiments are not limited thereto, and the edge electrode 110 may be disposed in an outer region inside the shower head body 70.

The upper electrode 50 may be provided in a first region corresponding to the wafer W inside the shower head body 70, and the edge electrode 110 may be provided in a second region corresponding to a peripheral region of the wafer W inside the upper portion of the chamber 20 surrounding the shower head body 70. The first region may be referred to as a central region PS1 of a plasma (or plasma sheath) region, and the second region may be referred to as an edge region PS2 of the plasma (or plasma sheath) region.

A plasma control circuit 130 may be electrically connected to the edge electrode 110 by a second transmission line 112. The plasma control circuit 130 may serve as a reflector configured to change the electrical boundary condition in the plasma edge boundary region EB in response to a first control signal S1 inputted from a controller 140. The plasma control circuit 130 may change characteristic impedance of the edge region PS2 of the plasma (or plasma sheath) region adjacent to the edge electrode 110 to controls the electrical boundary condition in the plasma edge boundary region EB.

As illustrated in FIG. 10, when a RF component F1 having a first high frequency (eg, 60 MHz) is supplied to the upper electrode 50, the component may move along a surface so that the plasma P is generated in the plasma chamber 20. When the RF power having the first frequency is applied to the plasma chamber 20, additional components (harmonic wave component, intermodulation distortion (IMD) frequency component) may be generated due to nonlinearity of the plasma.

Some of the frequency components F2 among the high frequency components existing in the plasma sheath may travel to the edge boundary region EB. The central region PS1 of the plasma sheath with the edge boundary region EB interposed therebetween may have a first medium by a power source circuit connected to the upper electrode 50, and the edge region PS2 of the plasma sheath may have a second medium different from the first medium by the plasma control circuit 130 connected to the edge electrode 110.

Accordingly, some of the frequency components F2 traveling to the edge boundary region EB may be reflected in the edge boundary region EB due to the difference between the first media and the second media, and some high frequency components F3 may be reflected back into the plasma sheath and some high frequency components F4 may pass through and proceed to the edge electrode 110. The traveling wave F2 traveling to the edge boundary region EB in the plasma sheath and the reflected wave F3 reflected from the edge boundary region EB may meet in the central region PS1 to form a standing wave. In the central region PS1 of the plasma sheath, the traveling wave and the reflected wave having the first frequency may meet each other to form a standing wave, the traveling wave and the reflected wave having the harmonic component may meet each other to form a standing wave, and the traveling wave and the reflected wave having the intermodulation frequency component may meet each other to form a standing wave.

The plasma control circuit 130 of the plasma control apparatus may control the electrical boundary condition in the plasma edge boundary region of the first frequency component, the harmonic component generated by nonlinearity of plasma and the intermodulation frequency components generated by the frequency component in the plasma chamber and each of the first frequency component and the harmonic component.

The plasma control apparatus may be substantially the same as or similar to the plasma control apparatus in FIG. 1. Thus, a detailed description thereof will be omitted.

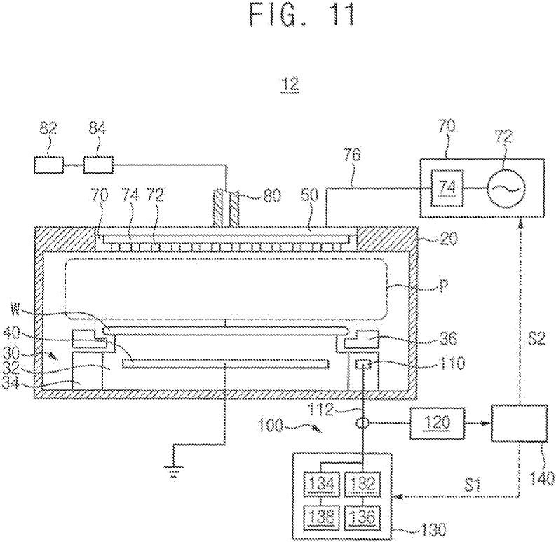

FIG. 11 is a block diagram illustrating a plasma processing system according to example embodiments. The plasma processing system may be substantially the same as or similar to the plasma processing system described with reference to FIGS. 1 to 5 except for an arrangement of a plasma power supply. Thus, same reference numerals will be used to refer to the same or like elements and any further repetitive explanation concerning the above elements will be omitted.

Referring to FIG. 11, a plasma power supply of a plasma processing system 12 may include a second power supply 70 configured to apply plasma source power to an upper electrode 50.

In example embodiments, the second power supply 70 may include an RF power source 72 and an RF matcher 76 as plasma source elements. The RF power source 72 may generate a radio frequency (RF) signal. The second power supply 70 may be substantially the same as or similar to the first power supply in FIG. 1. Thus, a detailed description thereof will be omitted.

A lower electrode 40 may be connected to the ground. Alternatively, a first power supply may be provided to supply RF power to the lower electrode 40. In this case, the lower electrode 40 may receive RF power from the first power supply, and may excite a source gas supplied into a chamber 20 into plasma in synchronization with the upper electrode 50.

In example embodiments, the edge electrode 110 may be disposed in an outer insulating ring 34. The edge electrode 110 may be disposed under a focus ring 36. The edge electrode 110 may have an annular shape. The edge electrode 110 may be provided adjacent to and surround the lower electrode 40 and may be arranged to be spaced apart from the lower electrode.

The upper electrode 50 may be provided in a first region corresponding to a wafer W inside a shower head 70, and the edge electrode 110 may be provided in a second region corresponding to a peripheral region of the wafer W inside the outer insulating ring 34 provided adjacent to and surrounding the support plate 32. The first region may be referred to as a central region PS1 of a plasma (or plasma sheath) region, and the second region may be referred to as an edge region PS2 of the plasma (or plasma sheath) region.

The edge electrode 110 may directly contact the focus ring 36 or may be electrically connected to the focus ring 36. The plasma control apparatus 100 may control an electrical boundary condition in the plasma edge boundary region EB through a plasma control circuit 130 electrically connected to the edge electrode 110 to provide one independent circuit path to change an electric field distribution of the standing wave in the chamber 20 to thereby improve uniformity of the plasma.

The plasma control apparatus may be substantially the same as or similar to the plasma control apparatus in FIG. 1. Thus, a detailed description thereof will be omitted.

The above plasma processing apparatus and method may be may be used to manufacture semiconductor devices including logic devices and memory devices. For example, For example, the semiconductor device may be applied to logic devices such as central processing units (CPUs), main processing units (MPUs), or application processors (APs), or the like, and volatile memory devices such as DRAM devices, SRAM devices, or non-volatile memory devices such as flash memory devices, PRAM devices, MRAM devices, ReRAM devices, or the like.

While example embodiments have been described with reference to the figures, it will be understood by those of ordinary skill in the art that various changes in form and details may be made therein without departing from the spirit and scope as defined by the following claims and their equivalents.

1-10. (canceled)

11. A plasma processing system comprising:
a plasma chamber comprising a plasma electrode;
a plasma power supply configured to apply radio frequency (RF) power having a fundamental frequency to the plasma electrode to generate plasma;
an edge electrode disposed adjacent to the plasma electrode and corresponding to a plasma edge boundary region;
a plasma control circuit electrically connected to the edge electrode, the plasma control circuit being configured to change an electrical boundary condition in the plasma edge boundary region based on an inputted control signal;
a sensor configured to obtain electrical signal data of the edge electrode; and
a processor configured to obtain the electrical boundary condition in the plasma edge boundary region based on the electrical signal data obtained by the sensor and output the control signal to the plasma control circuit to obtain a desired electrical boundary condition.

12. The plasma processing system of claim 11, wherein the edge electrode has an annular shape.

13. The plasma processing system of claim 11, wherein the plasma electrode comprises at least one of an upper electrode and a lower electrode.

14. The plasma processing system of claim 13, wherein when the plasma electrode comprises the lower electrode, the edge electrode is disposed adjacent to the lower electrode.

15. The plasma processing system of claim 14, further comprising:
a focus ring extending along a periphery of a substrate on the edge electrode.

16. The plasma processing system of claim 15, wherein the edge electrode is electrically connected to the focus ring.

17. The plasma processing system of claim 11, wherein the plasma control circuit comprises:
a fundamental frequency control circuit configured to change a boundary condition of the fundamental frequency;
a first intermodulation frequency control circuit configured to change a boundary condition of intermodulation distortion frequency components generated by a frequency component in the plasma chamber and the fundamental frequency;
a harmonic frequency control circuit configured to change a boundary condition of a harmonic wave component; and
a second intermodulation frequency control circuit configured to change a boundary condition of the intermodulation distortion frequency components generated by a frequency component in the plasma chamber and the harmonic wave component.

18. The plasma processing system of claim 17, wherein the plasma control circuit comprises an impedance control circuit or a filter control circuit.

19. The plasma processing system of claim 11, wherein the electrical signal data obtain by the sensor comprises voltage, current, and phase.

20. The plasma processing system of claim 11, wherein the sensor comprises a voltage current sensor.

21. A plasma processing system comprising:
a plasma chamber providing a space configured to process a substrate;
a substrate stage disposed within the plasma chamber to support the substrate, the substrate stage comprising a lower electrode;
a plasma power supply configured to apply radio frequency (RF) power having a fundamental frequency to the lower electrode to generate plasma;
an edge electrode disposed adjacent to the lower electrode and configured to control an electrical boundary condition in a plasma edge boundary region;
a plasma control circuit electrically connected to the edge electrode, the plasma control circuit being configured to change the electrical boundary condition in the plasma edge boundary region of a first frequency component, a harmonic wave component generated by nonlinearity of the plasma and intermodulation distortion frequency components generated by a frequency component in the plasma chamber and each of the first frequency component and the harmonic wave component;
a sensor configured to obtain electrical signal data of the edge electrode; and
a processor configured to obtain the electrical boundary condition in the plasma edge boundary region based on the electrical signal data obtained by the sensor and output a control signal to the plasma control circuit to obtain a desired electrical boundary condition.

22. The plasma processing system of claim 21, wherein the edge electrode has an annular shape.

23. The plasma processing system of claim 21, further comprising:
an electrode disposed to face the lower electrode.

24. The plasma processing system of claim 21, further comprising:
a focus ring disposed on an upper region of the substrate stage adjacent to the substrate.

25. The plasma processing system of claim 24, wherein the edge electrode is electrically connected to the focus ring.

26. The plasma processing system of claim 21, wherein the plasma control circuit is configured to change the electrical boundary condition to control a standing wave in the plasma chamber.

27. The plasma processing system of claims 26, wherein the plasma control circuit comprises:
a fundamental frequency control circuit configured to change a boundary condition of the fundamental frequency;
a first intermodulation frequency control circuit configured to change a boundary condition of the intermodulation distortion frequency components generated by a frequency component in the plasma chamber and the fundamental frequency;
a harmonic frequency control circuit configured to change a boundary condition of the harmonic wave component; and
a second intermodulation frequency control circuit configured to change a boundary condition of the intermodulation distortion frequency components generated by a frequency component in the plasma chamber and the harmonic wave component.

28. The plasma processing system of claims 27, wherein the plasma control circuit comprises an impedance control circuit or a filter control circuit.

29. The plasma processing system of claims 21, wherein the electrical signal data obtain by the sensor comprises voltage, current, and phase.

30. The plasma processing system of claims 21, wherein the sensor comprises a voltage current sensor.
